(19) United States
(12) Patent Application Publication
(10) Pub. No.: US 2012/0164782 A1
(43) Pub. Date: Jun. 28, 2012

(54) METHOD AND DEVICE FOR PRODUCING A PHOTOVOLTAIC THIN-FILM MODULE

(76) Inventor: Hermann Wagner, Jena (DE)

(21) Appl. No.: 13/320,435

(22) PCT Filed: May 12, 2010
(86) PCT No.: PCT/EP10/02933

§ 371 Date: Mar. 13, 2012

(30) Foreign Application Priority Data
May 14, 2009 (DE) 10 2009 021 273.6

(51) Int. Cl. H01L 31/0224; B23K 26/00

(52) U.S. Cl. 438/73; 219/121.6; 257/E31.124

(57) ABSTRACT

A photovoltaic thin-film module is provided that includes a substrate on which a transparent front electrode layer, a semiconductor layer, and a rear electrode layer are deposited as functional layers, which are provided with cell dividing lines for forming series-connected cells. The functional layers are ablated using a laser in the edge area. An insulation dividing line is formed in the edge region for the insulation between the front and rear electrode layers using a second laser. The ablation of the functional layers and the forming of the insulation dividing line are performed jointly in one step.

### CROSS REFERENCE TO RELATED APPLICATIONS

This application is a U.S. National Stage Entry under 35 U.S.C. §371 of PCT/EP2010/002933, filed on May 12, 2010, which claims the benefit of German Patent Application No. 10 2009 021 273,6, filed on May 14, 2009, the entire contents of both of which are incorporated herein by reference.

### BACKGROUND OF THE INVENTION

1. Field of the Invention

The invention relates to a method for producing a photovoltaic thin-film module and a device for carrying out the method.

2. Description of Related Art

On the back side opposite to the light-incident side, photovoltaic thin-film modules are provided with a rear cover, which is laminated onto the back side of the functional layers by means of an adhesive film. In order to ensure sufficient electrical insulation of the energized functional layers against the environment (frame, mounting rack etc.) in particular in the moist state, the adhesive film is directly connected to the substrate in the edge area of the module, thus achieving a hermetic encapsulation of the functional layers.

For this purpose, an edge ablation is performed, i.e. the functional layers are ablated completely in the edge area of the module. The edge ablation may be carried out mechanically, e.g. by sandblasting or grinding, or by means of a laser (cf. DE 20 2008 005 970 U1, DE 20 2008 006 110 U1).

In case of edge ablation it occurs, however, that the outer edge of the front electrode layer and the outer edge of the rear electrode layer are brought into contact with each other in places, which causes a short-circuit. In order to ensure the electrical insulation between the front and rear electrode layer, a so-called “isocut” is thus carried out, i.e. by means of a laser, an insulation dividing line is scribed through the functional layers at a distance from the area of the module ablated at the edges.

Several steps and facilities are necessary for carrying out the edge ablation and the isocut. In a first step, for example, the front electrode layer is provided with the cell dividing lines for the series connection of the individual cells of the module as well as the dividing line for the isocut by means of a laser, using a facility by which the front electrode layer is structured. After the coating of the front electrode layer with the semiconductor layer, its structuring with the cell dividing lines and the coating of the semiconductor layer with the rear electrode layer, the rear electrode layer is provided with the dividing line for the isocut adjacent to the cell dividing lines in another facility by means of a laser. Finally, the edge ablation is performed using a further facility.

Since the forming of the dividing lines for the isocut in the front electrode layer and the rear electrode layer as well as the edge ablation are performed by means of different facilities, the different tolerances in the individual processes have to be taken into account, e.g. with respect to the coefficient of thermal expansion of the substrate of the module, consisting, for example, of a glass panel, and different temperatures during the individual processes.

Therefore, the isocut is provided for at a distance of 1 millimeters (mm) and more from the ablated area of the module in the functional layers. In addition, the dividing line for the isocut in the semiconductor and rear electrode layer must have a considerable width in order that it reliably overlaps the dividing line for the isocut in the front electrode layer. For forming the isocut dividing line in the rear electrode layer, the laser beam has thus to be moved over the module in an offset manner in order to overlap the adjacent tracks.

For this reason, the scribing of the isocut takes very much cycle time. In addition, the usable active surface of the module and hence its performance are reduced due to the distance of 1 mm and more from the ablated edge area of the module. Since malfunctions are possible in each of the various facilities, losses of performance and failures of the modules may also occur in many cases.

### SUMMARY OF THE INVENTION

It is the technical problem of the invention to reliably produce within a short cycle time high-performance photovoltaic thin-layer modules ablated at the edges and provided with an isocut.

According to the invention, the photovoltaic module has a substrate on which a transparent front electrode layer, a semiconductor layer and a rear electrode layer are deposited as functional layers, each having a layer thickness covering a range from nanometres up to micrometres.

The substrate consists of an electrically non-conductive and—in case of a superstrate arrangement—a transparent material, for example glass. The front electrode layer may be made of an electrically conductive metal oxide, for example zinc oxide or stannic oxide. It is merely essential that it is transparent and electrically conductive and absorbs at least a small percentage of the laser radiation.

The semiconductor layer may consist of silicon, for example amorphous, microcrystalline or polycrystalline silicon, but also be another semiconductor, for example cadmium tellurium or CIGS, thus copper, indium, gallium, selenide. The rear electrode layer is preferably a metal layer, for example made of aluminium, copper, silver or the like.

The coating with the front electrode layer and the semiconductor layer is performed, for example, by means of plasma-enhanced chemical vapour deposition (PECVD), the coating with the rear electrode layer is preferably carried out by sputtering. The front electrode layer, the semiconductor layer and the rear electrode layer are each provided with cell dividing lines in order to form individual series-connected cells.

According to the invention, the ablation of the functional layers in the edge area of the module, thus the edge ablation, and the forming of the insulation dividing line in the edge area of the front electrode layer and the insulation dividing line in the edge area of the semiconductor and rear electrode layer, thus the isocut in the edge area of the functional layers, are performed jointly in one step by one facility.

That is to say while the functional layers in the edge area of the module are lasered, the dividing line in the edge area of the semiconductor and the rear electrode layer as well as the front electrode layer are lasered simultaneously for the isocut. According to the invention, the lasers including their optics for the edge ablation as well as for the forming of the insulation dividing lines, thus the isocut, are preferably mechanically permanently connected to each other in a laser unit.

Since the edge ablation and the isocut of the three functional layers are performed simultaneously according to the invention, tolerances of different facilities and influences of the substrate temperature are no longer relevant. It is thus possible to minimize the distance between the isocut and the edge ablation and to increase the performance of the module. In addition, the width of the dividing line for the isocut in the rear electrode layer can be minimized and even be reduced to zero and thus the performance of the module still be increased.

Compared to the state of the art, the scribing times are also reduced according to the invention, because the isocut lines are omitted when the front and back contacts are structured.

As laser for the edge ablation and for the forming of the dividing line in the edge area of the front electrode layer, a laser emitting infrared radiation and having a wavelength of at least 800 nanometers (nm) may be used, preferably a neodymium-doped yttrium vanadate (Nd:YVO₄) or an Nd:YAG laser, thus with yttrium aluminium garnet as host crystal, with a fundamental oscillation of 1064 nm. However, it is also possible to use, for example, a neodymium-doped solid-state laser at the triple frequency, thus a wavelength of 355 nm, when forming the dividing line in the edge area of the front electrode layer. For the forming of the dividing line in the edge area of the semiconductor layer and the rear electrode layer, a visible light-emitting laser is preferably used, in particular a neodymium-doped solid-state laser, thus an Nd:YVO₄ or Nd:YAG laser, at the double frequency with a wavelength of 532 nm.

Instead of neodymium-doped lasers, other lasers emitting in the infrared range with their fundamental oscillation may also be used, for example ytterbium-doped lasers having a fundamental wavelength of approximately 1070 nm. Also in this case, a doubling or tripling of the frequency can be achieved without any problems. As lasers, especially fibre lasers are used.

Preferably, a pulsed Q-switched laser is used, in particular, for the edge ablation and the forming of the dividing line in the edge area of the semiconductor and rear electrode layer.

In order to ensure a complete ablation of the functional layers in the edge area of the module, the laser beam of the laser for the edge ablation and the forming of the dividing line in the edge area of the semiconductor and rear electrode layer should have a high energy density of particularly at least 50 mJ/mm². Short laser pulses of less than 100 ns should be emitted. The pulse frequency may be 1 up to 50 kHz. The ablation of the functional layers in the edge area of the module, thus the edge ablation, can be carried out by means of a biaxial galvanic laser scanner. In this case, the focal spots are placed one behind the other pulse by pulse by means of the biaxial galvanic laser scanner so that a complete coverage without any major overlap losses is achieved. The fast scanner movement is superimposed by a much slower relative movement between the field processed by the scanner and the module. This relative movement may be 1 cm/second or more. The width of the area ablated at the edges may be 5 up to 20 mm, for example. The edge ablation and the isocut extend over the entire circumference of the generally rectangular module.

For the ablation of the functional layers in the edge area of the module, thus the edge ablation, as well as for the forming of the insulation dividing lines, thus the isocut, the laser beam is preferably focused onto the functional layers through the transparent substrate in each case.

When the isocut is formed, the laser beam of the laser for forming the dividing line in the rear electrode layer precedes the laser beam of the laser for forming the dividing line in the front electrode layer, because the laser beam for the dividing line in the front electrode layer is only capable of impinging on the front electrode layer after the dividing line in the rear electrode layer and the semiconductor layer has been formed.

The dividing line in the edge area of the semiconductor and rear electrode layer and the dividing line in the edge area of the front electrode layer are formed in the direction of movement of the module towards the laser unit by overlapping laser focal spots arranged one behind the other.

The ablation of the rear electrode layer is carried out in such a way that the semiconductor layer located in the laser focal spot evaporates and thus blasts off the overlying rear electrode layer in the area of the focal spot. Accordingly, the laser focal spots arranged one behind the other on the rear electrode layer may only overlap to such an extent that the energy input into the rear electrode layer does not cause the forming of holes in the rear electrode layer before the semiconductor material is heated to evaporating temperature, because otherwise the vapour escapes through the holes without blasting off the overlying rear electrode layer completely.

Preferably, the dividing line in the edge area of the semiconductor and rear electrode layer has a width larger than the width of the dividing line in the edge area of the front electrode layer. Thus, the width of the dividing line in the edge area of the semiconductor and rear electrode layer can, for example, be 80 to 150 micrometers (μm), preferably 100 to 150 μm, and the width of the dividing line in the edge area of the front electrode layer 20 to 60 μm, preferably 30 to 50 μm. In order to form a laser beam of corresponding width, the laser for the dividing line in the edge area of the semiconductor and rear electrode layer has laser optics by which the laser beam is widened. Preferably, the laser unit is arranged stationary, whereas the module is moved towards the laser unit. The device for moving the module can, for example, consist of a robot. The robot is preferably formed in such a way that it is capable of moving the module with its entire circumference along the laser unit in one direction. However, the laser unit may also be movable.

Based on the enclosed drawings, the invention is described in more detail below by way of example.

### BRIEF DESCRIPTION OF THE SEVERAL VIEWS OF THE DRAWINGS

The drawings each show schematically:

FIG. 1 a sectional view of a photovoltaic module including the edge area;

FIG. 2 the laser beams during the simultaneous edge ablation and the forming of the isocut;

FIG. 3 a top view of the overlapping laser focal spots arranged one behind the other in the semiconductor and rear electrode layer as well as in the front electrode layer;

FIG. 4 a top view of the laser unit; and

FIG. 5 a top view of a device for moving the module towards the laser unit according to FIG. 4.

### DETAILED DESCRIPTION OF THE INVENTION

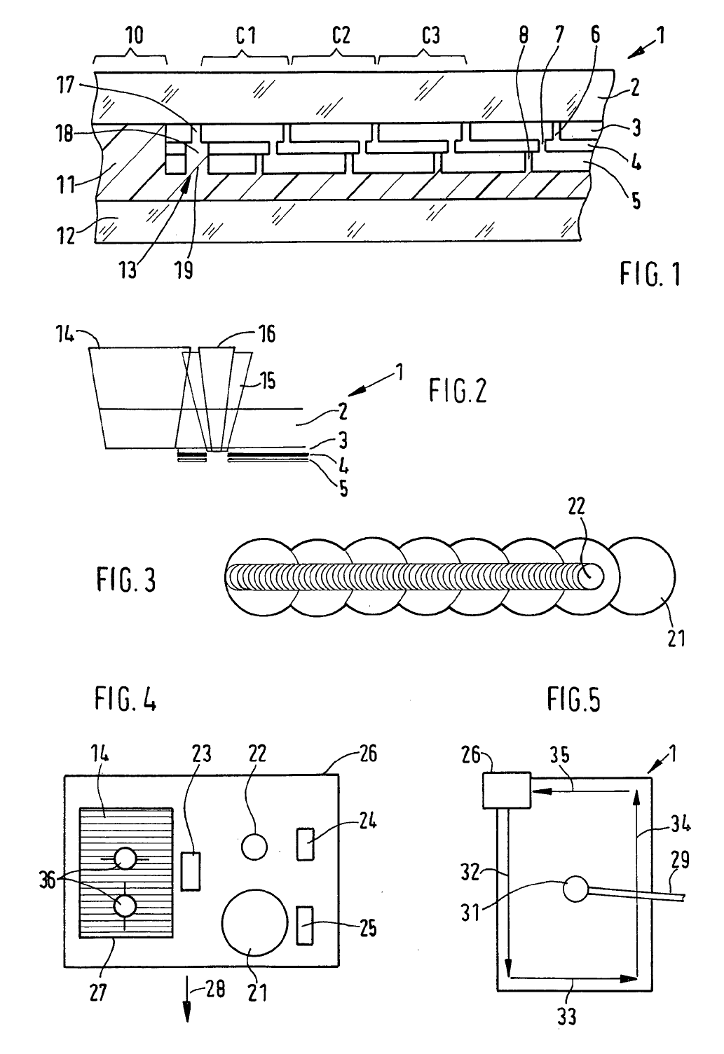

According to FIG. 1, the photovoltaic thin-film module comprises a transparent substrate 2, e.g. a glass panel, on which three functional layers, namely a front electrode layer 3, a semiconductor layer 4, for example of amorphous silicon, and a rear electrode layer 5 are deposited on top of each other.

The module consists of individual strip-type cells C1, C2, C3 etc. being connected in series by structure lines 6, 7, 8. The electric current generated can be collected on the other side of the module 1 by contacting the two outer cells of the module, thus the cell C1 and the cell not illustrated.

In the edge area 10 of the module 1, the functional layers 3, 4, 5 are removed completely. By means of the adhesive film 11, for example an EVA or PVB film or another hot melt adhesive film, a rear cover 12, for example a glass panel or plastic film, is laminated onto the side of the substrate 2 which is provided with the functional layers 3, 4, 5. By means of the adhesive film 11, the substrate 2 is directly connected permanently to the rear cover 12 in the edge area 10, thus encapsulating the functional layers 3 to 5 in the module 1 such that they are separated from the environment with a high electrical insulation resistance even under different climatic conditions, in particular in the event of humidity.

For the ablation of the three functional layers 3 to 5, an Nd:VO₄ solid-state laser having a fundamental wave length of 1064 nm is used, for example. Since the outer edges of the front electrode layer and the rear electrode layer may join in places when the edge area 10 is lasered, an isocut 13 is carried out, i.e. an insulation dividing line 13 is lasered in the edge area of the functional layers 3 to 5 for the insulation between the front electrode layer 3 and the rear electrode layer 5.

According to FIG. 2, the ablation of the functional layers 3 to 5 in the edge area 10 of the module 1 and the forming of the insulation dividing lines 13 are performed jointly in one step by means of three lasers 23, 25, 24 (FIG. 4) emitting the laser beam 14 for the ablation of the edge area of the module 1, thus the edge ablation, the laser beam 15 for the forming of the dividing line 18, 19 in the semiconductor layer 4 and the rear electrode layer 5 as well as the laser beam 16 for the forming of the dividing line 17 in the front electrode layer 3 in the edge area of the three functional layers 3 to 5.

When the wide laser beam 14 for the edge ablation with a biaxial galvanic laser scanner 36 (FIG. 4) impinges on the functional layers 3 to 5, the laser beam 15 for the forming of the dividing lines 18 and 19 in the semiconductor layer 4 and the rear electrode layer 5 as well as the laser beam 16 for the forming of the dividing line 17 in the front electrode layer 3 produce overlapping round focal spots 21, 22 arranged one behind the other, as shown in FIG. 3, with the focal spots 22 for forming the dividing lines 18, 19 in the edge area of the semiconductor layer 4 and/or the rear electrode layer 5 having a larger diameter than the focal spots 21 for forming the dividing line 17 in the front electrode layer 3. At the same time, not only the dividing line 17 in the front electrode layer 3 is formed but also the dividing line 18, 19 in the semiconductor layer 4 and the rear electrode layer 5 by a single track of focal spots 21, 22 arranged one behind the other.

According to FIG. 4, the lasers 23, 24 and 25 generating the laser beams 14, 15 and/or 16 are mechanically permanently connected to each other in a single laser unit 26 together with the focussing optics not illustrated and the bearings in which the biaxial galvanic laser scanner 36 is pivoted. Rectangular adjacent fields 27 arranged one behind the other are thus produced by means of the biaxial galvanic laser scanner 36 of the laser 23, whereas the laser beams 16 and 15 of the lasers 24, 25 produce the round focal spots 21, 22.

Whereas the laser unit 26 is arranged stationary, the module 1 is moved in the direction of the arrow 28. The focussing optics for the laser beam 15 is aligned in such a way that it precedes the laser beam 16 in the direction of movement 28 (FIG. 3); i.e. in the unit 26, the focussing optics for the laser beam 15 is arranged in the direction of movement 28 in front of the focussing optics for the laser beam 16.

According to FIG. 5, the module 1 is moved towards the stationary laser unit 26 by means of an arm 29 of a robot not illustrated, which engages with the substrate 2 from above, for example by means of a suction cup 31, in the direction of the arrows 32 to 35 so that the module 1 is moved with its entire circumference in one direction in such a way that the laser beam 15 for forming the dividing lines 18, 19 in the semiconductor layer 4 and the rear electrode layer 5 is always arranged in front of the laser beam 16 for forming the dividing line 17 in the front electrode layer 3 in the direction of movement 32 to 35 of the module 1.

1. A method for producing a photovoltaic thin-film module having a substrate on which a transparent front electrode layer, a semiconductor layer and a rear electrode layer are deposited as functional layers, which are provided with cell dividing lines for forming series-connected cells, the method comprising:
using a first laser in an edge area of the photovoltaic thin-film module to ablate the functional layers,
forming, using a second laser, a first insulation dividing line in the edge area of the functional layers in the front electrode layer, and
forming, using a third laser, second and third insulation dividing lines in the semiconductor layer and the rear electrode layer,
wherein the ablation of the functional layers and the forming of the first insulation dividing line are performed jointly in one step.

2. The method according to claim 1, wherein the first, second, and/or third lasers comprise a neodymium-doped or ytterbium-doped solid-state laser having a wavelength in the infrared range.

3. The method according to claim 1, wherein the step of using the first laser comprises using a neodymium-doped or ytterbium-doped solid-state laser at the triple frequency.

4. The method according to claim 1, wherein the step of forming the second and third insulation dividing lines comprises using a neodymium-doped or ytterbium-doped solid-state laser at the double frequency.

5. The method according to claim 1, wherein the first, second, and/or third lasers comprise a pulsed laser.

6. The method according to claim 1, wherein the ablation of the functional layers comprises using a biaxial galvanic laser scanner.

7. The method according to claim 1, further comprising focusing the first, second, and third lasers through a transparent substrate.

8. The method according to claim 1, wherein the step of forming the second and third insulation dividing lines precedes the step of forming the first insulation dividing line.

9. The method according to claim 5, wherein the second and third insulation dividing lines is formed by overlapping laser focal spots arranged one behind the other.

10. The method according to claim 9, wherein the step of overlapping of the laser focal spots is carried out in such a way that in the third insulation dividing line no holes are formed through which evaporated semiconductor material can escape.

11. The method according to claim 9, wherein the first and second insulation dividing lines are formed by a single track of the overlapping laser focal spots arranged one behind the other.

12. The method according to claim 1, wherein the second and third insulation dividing lines each have a width larger than a width of the first insulation dividing line.

13. The method according to claim 12, wherein the width of the second and third insulation dividing lines is 80 to 150 μm, and the width of the first insulation dividing line is 20 to 60 μm.

14. A device for carrying out the method according to claim 1, wherein the first, second, and third lasers including optics that are permanently connected to each other in a laser unit.

15. The device according to claim 14, wherein the laser unit comprises a biaxial galvanic laser scanner.

16. The device according to claim 14, wherein the third laser has laser optics by which a laser beam that is focused on the semiconductor layer and the rear electrode layer is widened.

17. The device according to claim 16, wherein the laser optics is arranged in a direction of movement in front of a laser beam of the second laser in the event that the laser unit (26) is moved relative to the module.

18. The device according to claim 14, wherein the laser unit is arranged stationary and further comprising a device for moving the module.

19. The device according to claim 18, wherein the device for moving the module is formed in such a way that the module is movable with an entire circumference along the laser unit in one direction that a laser beam of the third laser is always arranged in front of a laser beam of the second laser.
